(19) United States
(12) Patent Application Publication
(10) Pub. No.: US 2011/0255228 A1
(43) Pub. Date: Oct. 20, 2011

(54) BALANCE SIGNAL OUTPUT TYPE SENSOR

(75) Inventors: Norio KIMURA, Kanagawa (JP); Shigeo Masai, Osaka (JP); Yasuhiro Nakanosai, Fukushima (JP)

(73) Assignee: Panasonic Corporation, Osaka (JP)

(21) Appl. No.: 13/168,625

(22) Filed: Jun. 24, 2011

Related U.S. Application Data
(63) Continuation of application No. PCT/JP2009/007081, filed on Dec. 21, 2009.

(30) Foreign Application Priority Data
Dec. 24, 2008 (JP) P.2008-328492

(51) Int. Cl. H05K 5/00; H03M 3/00; H03F 3/68

(52) U.S. Cl. 361/679.01; 330/124 R; 330/307; 341/143

(57) ABSTRACT

There is provided a balance signal output type sensor producing a high quality balance signal output. There is provided a balance signal output type sensor including a capacitor unit having a first electrode serving as a movable electrode and a second electrode disposed opposite the first electrode, a first amplifier that is connected to the first electrode and that amplifies a signal from the first electrode, and a second amplifier that is connected to the second electrode and that amplifies a signal from the second electrode.

### BACKGROUND

The present invention relates to a balance signal output type sensor and a sensor unit and, more particularly, a balance signal output type sensor and a sensor unit that effectively utilize electric charges developed in two mutually-opposed electrodes in a capacitor unit and that produce a balance output of a highly sensitive, high quality signal having a high signal-to-noise ratio.

A balance signal output type sensor outputs an electric signal based on vibrations or oscillations of mutually-opposed electrodes arranged in a capacitor unit via static energy. The types of balance signal output type sensors include a capacitor microphone, a pressure sensor, and an acceleration sensor. The capacitor microphone and the pressure sensor sense vibrations of mutually-opposed electrodes. The acceleration sensor senses oscillation. In the present specification, the balance signal output type sensor is sometimes called as a sensor simply.

An explanation is given by taking a microphone as an example. An output signal of a sensor produced during collection of conversations is an extremely faint signal of the order of 3 mV to 10 mV. Well-known balance connection transmission is a process for suppressing external noise included in the faint signal during transmission of the signal.

Patent Document 1 shows a configuration in which one terminal of mutually-opposed electrodes of an electret capacitor microphone is connected to a diode, a gate resistor, and a gate of an FET and the other electrode is connected to a ground line.

Patent Document 2 shows a balance output type capacitor microphone having two capacitor microphones, namely, a first capacitor microphone and a second capacitor microphone. The microphone is configured such that an output signal from the first capacitor microphone and an output signal from the second capacitor microphone are opposite in phase to each other.

Non-patent Document 1 discloses a two-terminal electrets capacitor microphone used primarily in a portable phone, or the like. The electret capacitor microphone is connected to a power source via a pull-up load resistor. The electret capacitor microphone is connected to a ground line through a pull-down load resistor. The electret capacitor microphone is given such a configuration, thereby turning into a circuit that produces a pseudo balance output.
[Patent Document 1] JP-A-2006-33091
[Patent Document 2] JP-A-2008-005439

### [Non-Patent Document]

[Non-Patent Document 1] TS472 IC Datasheet by ST Microelectronics Co., Ltd.

However, if noise is mixed into the electret capacitor microphones described in Patent Document 1 and Non-Patent Document 1, the noise will be amplified as it is, which therefore raises a problem of the inability to cancel the mixed noise.

The balance output type capacitor microphone described in Patent Document 2 is configured so as to cancel noise by use of two capacitor microphones in a pair. Therefore, there is a problem that the balance output type capacitor microphone itself becomes large size. Further, the first capacitor microphone and the second capacitor microphone are required to exhibit paired sensitivity, which in turn raises a problem of narrowing of an allowable range required during manufacture of the balance output type capacitor microphone and deterioration of yields.

### SUMMARY

In light of the problem, the present invention aims at providing a balance signal output type sensor capable of reducing noise mixed into a capacitor unit and also enhancing signal quality.

The present invention is not required to resolve all of the problems, and the essential requirement for the present invention is to solve at least one of the problems. Further, the present invention is not required to accomplish all of the objectives, and the essential requirement for the present invention is to accomplish at least one of the objectives.

In order to achieve the above object, according to the present invention, there is provided a balance signal output type sensor, comprising:

a capacitor unit configured to have a first electrode serving as a movable electrode and a second electrode arranged opposing the first electrode;

a first amplifier connected to the first electrode and amplifies an output signal from the first electrode; and

a second amplifier connected to the second electrode and amplifies an output signal from the second electrode.

The balance signal output type sensor is assumed to designate a sensor that outputs a so-called balance signal that represents, in the form of a signal, a potential difference between a pair of signal lines (two lines).

In the balance signal output type sensor of the present invention, the capacitor unit includes the first electrode and the second electrode which are disposed opposite each other and acts as one capacitor. In the capacitor unit, the first electrode is connected to the first amplifier, and the second electrode is connected to the second amplifier. As a consequence, electric charges belonging to the first electrode and electric charges belonging to the second electrode can be sent respectively to different amplifiers. Therefore, there is yielded an advantage of the ability to effectively utilize the electric charges belonging to the first electrode and the electric charges belonging to the second electrode.

Moreover, complementary electric charges develop in the respective electrodes in response to motions of vibrating electrodes (the movable electrodes) caused by sound waves or vibrations, so that signals, like voltages of respective electrodes, become opposite in phase to each other. Amplified signals also become opposite in phase to each other in the same manner. In the meantime, when external noise is mixed into the capacitor unit, noise signals of respective electrodes become in phase to each other. Therefore, the signals are delivered as a balance signal output and utilized by a balance connection. There is also yielded an advantage of the ability to double sensitivity of the sensor and reduce external noise and disturbing noise mixed into the capacitor unit.

Preferably, the balance signal output type sensor further comprises a case, the case contains the capacitor unit, the first amplifier, and the second amplifier.

There is yielded an advantage of the ability to miniaturize the sensor and diminish external noise.

Preferably, the case is configured by a board and a cover member which covers the board on which the capacitor unit is mounted, and either one of the board and the cover member has an inlet port for transmitting pressure to the capacitor unit. Needless to say, the term “pressure” means sounds, or the like.

Preferably, the board has a first face and a second face which is opposed to the first face, the capacitor unit, the first amplifier, and the second amplifier are provided on the first face of the board, and an output terminal of the first amplifier, an output terminal of the second amplifier, a power supply terminal, and a ground terminal are provided on the second face of the board.

Preferably, the cover member is made of metal, and the ground terminal is electrically connected to the cover member through the board.

As a result of adoption of such a configuration, the ground terminal is electrically connected to the cover member, so that the chance of entry of electromagnetic noise from the outside of the case can be reduced.

Preferably, the balance signal output type sensor further comprises an another capacitor unit configured to have a same configuration of the capacitor unit.

Preferably, the first electrode of the capacitor unit and a first electrode of the another capacitor unit are respectively connected to an input terminal of the first amplifier, and the second electrode of the capacitor unit and a second electrode of the another capacitor unit are respectively connected to an input terminal of the second amplifier.

By such a configuration, it is possible to reduce the overall size of the balance signal output type sensor. Further, as a result of a plurality of capacitor units being provided, a signal having a high degree of sensitivity and a high SN ratio can be produced.

Preferably, a dielectric film is formed on a face of the first electrode which faces to the second electrode or a face of the second electrode which faces to the first electrode. As a result of adoption of such a configuration, the respective electrodes can acquire complementary electric charges by virtue of the electric charges held on the dielectric film.

Preferably, the dielectric film is an electret film. By adoption of such a configuration, the dielectric film is an electret film permanently holding electric charges. This yields an advantage of obviation of a necessity to feed electric charges by application of an external voltage to the sensor. The external voltage to be applied includes a polarization DC voltage, or the like. Further, since a connection line intended for applying a voltage to the capacitor unit becomes unnecessary, there is eliminated influence of the connection line on electric charges or voltages that develop in the first electrode and the second electrode, which are disposed opposite each other. Therefore, signals from the two electrodes become completely complementary signals.

When a capacitance element unit not having an electret film is taken as an objective, the DC bias voltage unit, two resistive components, and two capacitive components are connected together, whereby a capacitance element unit having a function equivalent to that of the electret can be formed, and the balance signal output type sensor can be formed.

Preferably, the first amplifier and the second amplifier configure a capacitively coupled charge amplifier.

Preferably, the first amplifier and the second amplifier are formed in an Integrated circuit.

Preferably, the output signal from the first amplifier is substantially opposite in phase to the output signal from the second amplifier.

Preferably, the first electrode is not connected to a ground (a connection to a ground potential). Also, it is preferable that the second electrode is not connected to the ground.

Preferably, the capacitor unit is a MEMS element unit. The capacitor unit is an MEMS element unit formed through semiconductor processes, whereby the capacitor unit can be miniaturized, and the entire balance signal output type sensor can be miniaturized.

The sensor unit can also be said to be built by mounting the capacitor unit, the first amplifier, and the second amplifier on a first face of a single printed board, connecting the first electrode of the capacitor unit and the first amplifier by a bonding wire, or the like, connecting the second electrode of the capacitor unit and the second amplifier by a bonding wire, or the like, arranging the output terminal of the first amplifier, the output terminal of the second amplifier, the terminal for supplying a voltage to the amplifiers, and the ground terminal (a reference potential terminal), as external connection terminals, on the second face of the printed board, and affixing a metal cap to the board so as to cover the capacitor unit, the first amplifier, and the second amplifier. The entire case housing the capacitor unit, the first amplifier, and the second amplifier can also be called a sensor unit. The sensor unit is affixed to a board of a portable phone, or the like, to thus act as a sensor. Further, an inlet port for introducing sound waves, pressure, or the like, to the capacitor unit is formed in the cap or the printed board. The sensor unit can also be called a mountable package.

Needless to say, it is possible to combine the foregoing characteristics with each other, as required, so as to avoid occurrence of a contradiction. For instance, it is naturally possible to adopt a configuration in which a plurality of MEMS elements, the first amplifier, and the second amplifier are housed in one case. Moreover, even when the respective characteristics can be expected to yield a plurality of advantages, there is no requirement that all of the advantages should be exhibited.

According to the present invention, there is also provided a digital signal output type sensor comprising:

the balance signal output type sensor according to claim 1; and

an analog-digital converter that converts an analog signal to a digital signal,

wherein the analog-digital converter converts the output signal from the first amplifier and the output signal from the second amplifier and outputs a digital output signal.

The digital signal output sensor is assumed to refer to a sensor that produces digital signals “1” and “0” from a signal (sound, vibrations, oscillations, or the like) input to the sensor.

Preferably, the first amplifier, the second amplifier, and the analog-digital converter are provided on a single board (a semiconductor integrated circuit).

Preferably, the analog-digital converter is a delta-sigma converter.

Preferably, the analog-digital converter outputs as the digital output signal a pulse density modulated with pulse density modulation process.

Preferably, the digital signal output type sensor further comprises a digital signal processor that converts the pulse density to an output signal in audio interface format.

According to the present invention, it is possible to provide a balance signal output type sensor that can cancel and suppress mixed external noise by use of complementary signals produced by both electrodes of a capacitor unit. Further, by a connection configuration that enables effective utilization of the complementary signals, loss reduction and sensitivity enhancement can be accomplished.

### BRIEF DESCRIPTION OF THE DRAWINGS

The above objects and advantages of the present invention will become more apparent by describing in detail preferred exemplary embodiments thereof with reference to the accompanying drawings, wherein:

FIG. 1 is a drawing showing a connection configuration of a balance signal output type sensor according to a first embodiment of the present invention;

FIGS. 2A and 2B are drawings showing a balance signal output type sensor chip according to the first embodiment of the present invention, wherein FIG. 2A is a cross sectional view of the balance signal output type sensor chip and FIG. 2B is a drawing showing an example equivalent circuit of the balance signal output type sensor chip;

FIGS. 3A to 3F are drawings showing an example mount configuration of the balance signal output type sensor according to the first embodiment of the present invention;

FIGS. 4A to 4C are drawings showing a characteristic of the balance signal output type sensor according to the first embodiment of the present invention;

FIG. 5 is a drawing showing a connection configuration of a balance signal output type sensor according to a second embodiment of the present invention;

FIGS. 6A to 6F are drawings showing an example mount configuration of the balance signal output type sensor according to the second embodiment of the present invention;

FIGS. 7A and 7B are drawings showing characteristics of the balance signal output type sensor according to the second embodiment of the present invention;

FIG. 8 is a cross sectional view showing an electrode structure of a balance signal output type sensor according to a first modification of the present invention;

FIG. 9 is an oblique perspective view of the electrode structure of a balance signal output type sensor;

FIG. 10 is a cross sectional view showing an electrode structure of a balance signal output type sensor according to a second modification of the present invention;

FIG. 11 is an oblique perspective view of the electrode structure of the balance signal output type sensor;

FIG. 12 is a cross sectional view showing an electrode structure of a balance signal output type sensor according to a third modification of the present invention;

FIG. 13 is a cross sectional view showing an electrode structure of the balance signal output type sensor according to the third modification of the present invention;

FIG. 14 is a drawing showing a connection configuration of a digital output sensor according to a third embodiment of the present invention;

FIGS. 15A and 15B are general drawings of a circuit diagram of an MEMS element unit according to a fourth embodiment of the present invention; and

FIG. 16 is a general drawing of a circuit diagram equivalent to a capacitor microphone according to the fourth embodiment of the present invention.

### DETAILED DESCRIPTION OF EXEMPLARY EMBODIMENTS

### First Embodiment

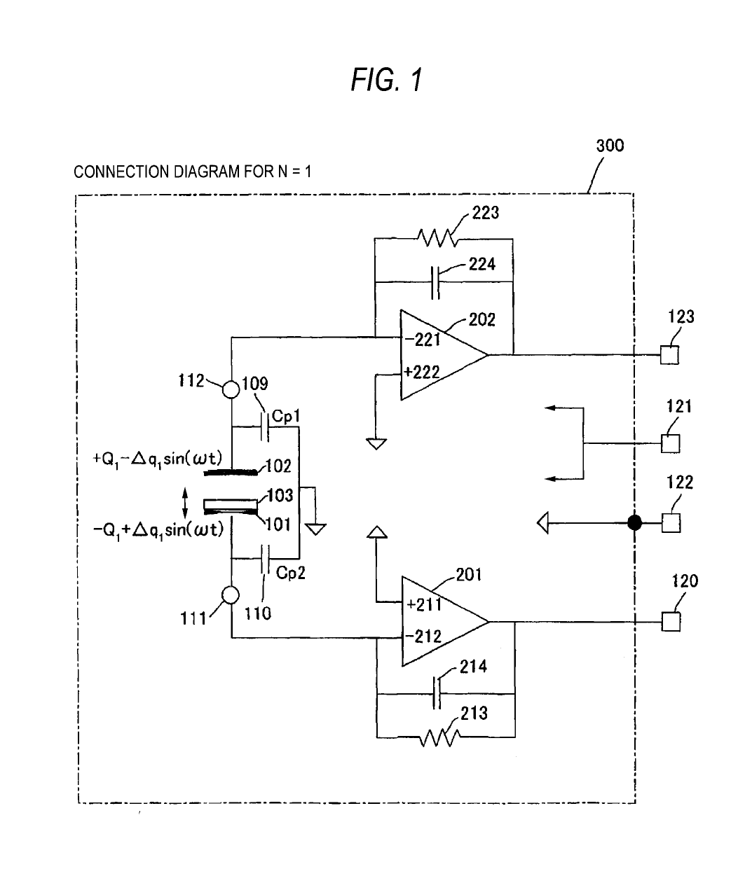

A first embodiment of the present invention is hereunder described in detail by reference to FIGS. 1 through 4. Further, materials and numerals employed in the present invention illustrate preferred embodiments, and the present invention is not limited to the embodiment. The present invention is susceptible to changes, as required, without departing a scope of concept of the present invention. In addition, the present embodiment can also be combined with another embodiment. A capacitor unit of a balance signal output type sensor is herein a MEMS element unit and, in particular, described as an MEMS element unit having an electret. A capacitor microphone (an MEMS microphone) is described as an example MEMS element unit. As will be described later, the MEMS element unit designates a capacitor fabricated by use of semiconductor processes. The above can be commonly applied to the present invention.

FIG. 1 is a general drawing of a circuit diagram equivalent to a balance signal output type sensor according to the first embodiment of the present invention.

As shown in FIG. 1, the balance signal output type sensor mainly includes an MEMS element unit having a first electrode 101 that is a movable electrode and a second electrode 102 that is disposed opposite the first electrode 101, a first amplifier 201 that is connected to the first electrode 101 of the MEMS element unit and that amplifiers a signal output from the first electrode 101, and a second amplifier 202 that is connected to the second electrode 102 and that amplifies a signal output from the second electrode 102. An electret film 103 is formed on a face of the first electrode facing the second electrode. The electret film 103 can also be formed on a face of the second electrode facing the first electrode. The electret film 103 is a film that holds electric charges substantially permanently.

The first electrode 101 is connected to an inverting input terminal 212 of the first amplifier 201 by way of a first electrode terminal 111. The second electrode 102 is connected to an inverting input terminal 221 of the second amplifier 202 by way of a second electrode terminal 112. The first amplifier 201 and the second amplifier 202 exhibit the same performance. A non-inverting input terminal 211 of the first amplifier 201 and a non-inverting input terminal 222 of the second amplifier 202 are connected to a ground line.

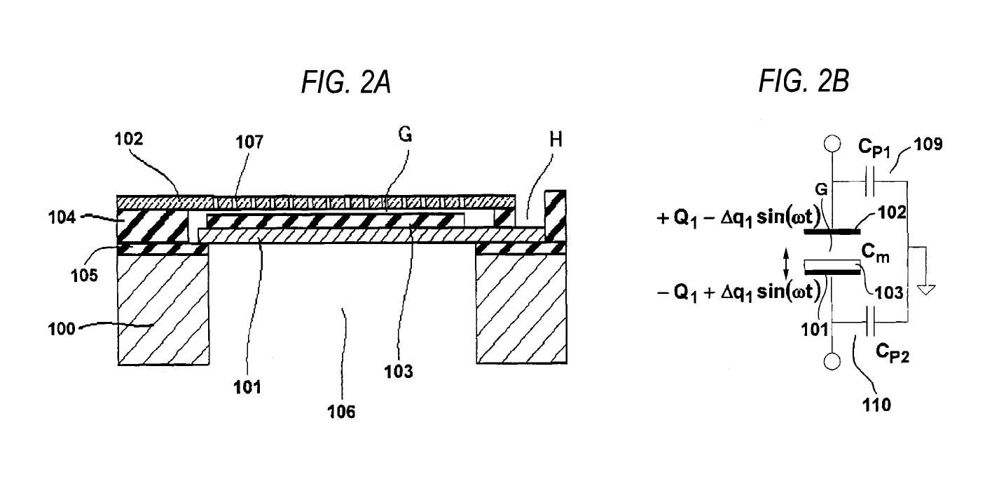

Parasitic capacitances 110 and 109 (see FIG. 2B) attributable to a floating structure and mounting of the MEMS element unit exist in the first electrode 101 and the second electrode 102, respectively.

The first amplifier 201 and the second amplifier 202 are high input impedance amplifiers and preferably of CMOS type amplifiers intended for accomplishing high input impedance. Two-source power that is a positive and negative source powers can also be used as an operation power source. However, the first amplifier 201 and the second amplifier 202 are preferably high input impedance CMOS amplifiers that operate from a single power source.

Feedback resistors 213 and 223 connected, respectively, to the first amplifier 201 and the second amplifier 202 are discharging resistors for preventing saturation of the first and second amplifiers 201 and 202. Feedback capacitors 214 and 224 connected, respectively, to the first amplifier 201 and the second amplifier 202 determine a degree of amplification of electric charges. A structure having the amplifiers, the feedback resistors, and the feedback capacitors can also be called a capacitively coupled electric charge amplifier.

Signals output from the first amplifier 201 and the second amplifier 202 are output, respectively, to external balance signal output terminals 120 and 123. A terminal 121 is a terminal for feeding a voltage to the amplifier, and a terminal 122 is a ground terminal (serves as a reference potential). The ground terminal is also connected to a case constituent member 300 that also serves as a shield and exhibits an effect of reducing a chance of electromagnetic noise being mixed into a signal from the outside.

FIG. 2A is a cross sectional view of the MEMS element unit of the first embodiment of the present invention, and FIG. 2B is a general drawing of a circuit diagram of the MEMS element unit according to the first embodiment of the present invention. The MEMS element unit is fabricated by finally separating into pieces a plurality of microphone chips simultaneously fabricated on a silicon substrate (a silicon wafer) by utilization of a process technique for fabricating a CMOS (a complementary type field effect transistor). FIG. 2A shows a cross sectional view of one of the thus-separated microphone chips.

As shown in FIG. 2A, the MEMS element unit has an n-type silicon substrate 100, a silicon oxide film 105 formed on the silicon substrate 100, the first electrode 101 that acts as an oscillatory electrode formed on a face of the silicon oxide film 105, the electret film 103 formed on a face of the first electrode 101, a spacer unit 104 made of a vitrified silicon film, the second electrode 102 acting as a stationary electrode supported by the spacer unit 104, and a through hole 106 formed by etching the silicon substrate 100. A plurality of apertures 107 that are to serve as sound apertures are formed in the second electrode, and an air gap G exists in a space sandwiched between the first electrode and the second electrode. A contact hole H for electrical connection is additionally formed in the MEMS element unit. The first electrode and the second electrode are made of an n-doped polysilicon film, and the electret film 103 is a film made by imparting electret ability to a silicon oxide film formed on the first electrode 101. The air gap G is made by etching away an area where the spacer unit is originally formed, however, the air gap can also be made by another method. The plurality of apertures 107 are openings for guiding a sound wave to the first electrode 101 that is a vibratory membrane. Sound waves transmitted through the plurality of apertures 107 vibrate a vibratory membrane made of the first electrode, or the like, whereby the MEMS element unit acts as a capacitor microphone. Dielectric films, like a silicon oxide film and a silicon nitride film, are stacked on the second electrode 102 serving as a stationary electrode. The first electrode 101 and the second electrode 102 act as a pair of capacitors.

An additional explanation is now given to the electret film 103. First, the plurality of MEMS element units fabricated on the silicon substrate (the wafer) are separated into pieces of chips. Subsequently, the thus-separated chips are subjected to electret treatment by a corona discharge, or the like, thereby imparting electret capability to the dielectric film. As a consequence, the electret film 103 can be caused to hold electric charges. Needless to say, a wafer can be imparted with electret ability. Depending on a property of an electret film, the electret film is usually given with negative electric charges.

Since the electret film is made of an inorganic film, like a silicon oxide film and a silicon nitride film, the electret film does not cause deterioration of its charge retention characteristic even when exposed to high temperatures when compared with another electret microphone utilizing a polymeric film, like an FEP, and is suitable for use as a sensor to be mounted by solder reflow process.

A circuit diagram of the MEMS element unit is now described by reference to FIG. 2B. The following appears as electric charges on the first electrode 101 having a film given the electret ability (i.e., the electret film 103); namely,

electric charges on the first electrode: −Q [C], and

the following appears as electric charges on the second electrode 102 serving as an opposite electrode; namely,

electric charges on the second electrode: +Q [C].

Thus, a state of equilibrium is accomplished.

In the state of equilibrium, capacitance Cₘ formed by the mutually opposed electrodes depends on the air gap G and an area of the electrodes to thereby assume a unique value.

$$\begin{matrix} & [ Mathematical Expression 1 ] \\ {C}_{m} = \frac{{ɛ}_{0} {ɛ}_{S} S}{G} [ F ] & \end{matrix}$$

where terms represent the followings: namely,

∈₀: a dielectric constant of vacuum: 8.85E−12 [F/m]

∈_{S}: a dielectric constant of air: 1.000586

S: an area of the electrodes [m²]

G: a gap length [m].

Further, the capacitance Cₘ can be easily made, on the silicon substrate 100, in the form of a floating structure that is not connected to a ground, as represented by an equivalent circuit shown in FIG. 2B.

When a sinusoidal sound wave having a single frequency is guided, in this state of equilibrium, to the first electrode 101 through the plurality of sound apertures 107 of the second electrode 102, the first electrode 101 acting as a vibratory membrane causes sinusoidal vibrations at the same frequency as that of the sound wave. Magnitude of displacements attributable to minute vibrations is roughly determined by rigidity of the vibratory membrane.

The vibrations cause a change in the capacitance Cₘ in the state of equilibrium, thereby causing a change in the electric charges of the electrodes 101 and 102.

[Mathematical Expression 2]

Provided that displacements in the state of equilibrium of the first electrode caused by the minute vibrations are Δξ sin(ωt), complementary minute variations will occur in the electric charges at the same frequency.

Namely, there occur

electric charges of the first electrode: −Q+Δq sin(ωt), and

electric charges of the second electrode: +Q−Δq sin(ωt).

The minute charge variations are also represented as minute voltage variations.

$$[ Mathematical Expression 3 ]$$

$$A voltage of the first electrode \text{:} + \frac{Δ q sin ( ϖ t )}{{C}_{m}}$$

$$A voltage of the second electrode \text{:} - \frac{Δ q sin ( ϖ t )}{{C}_{m}}$$

Moreover, as a result of the capacitor unit being provided with the floating structure, inherent parasitic capacitance depending on the structure shown in FIG. 2A occurs. The parasitic capacitance 110 occurs between the first electrode 101 and the silicon substrate 100. Moreover, the parasitic capacitance 109 occurs between the second electrode 102 and the silicon substrate 100. Further, even when a chip is mounted onto a printed board by bonding, parasitic capacitance occurs by way of the silicon substrate 100.

Accordingly, the MEMS microphone chip is represented as an equivalent circuit, such as that shown in FIG. 2B. Capacitance of the capacitor unit is represented by Cₘ, and each of the pieces of parasitic capacitance 109 and 110 is represented as C_{P1} and C_{P2}. Since the parasitic capacitance C_{P1} and C_{P2} correspond to capacitance occurring in lines, or the like, of the electrodes, vibrations do not occur. No electric charges occur in the two pieces of capacitance, in other words, an electromotive voltage ascribable to sound does not arise.

In relation to a DC-biased capacitor microphone, an electret capacitor microphone, and an electret MEMS microphone, there has never been discussed consideration to the above-described charge changes in the mutually opposed electrodes.

The DC-biased capacitor microphone has adopted a basic configuration and structure for applying a polarization DC voltage to either electrode ever since E. C. Wente conceived the capacitor microphone in the early years of 1900s. Therefore, either electrode is inevitably connected to a ground line (a ground potential). For this reason, signal charges flow into the ground line, so that consideration has never been given to utilization of the signal charges in both electrodes.

G. M. Sessler materialized an electret from a Teflon (Registered Trademark) film in the 1960s and applied the electret to a capacitor microphone. The microphone has been introduced as an electret capacitor microphone and widely been used in, for instance, portable phones, in this day and age. Even when such an electret capacitor microphone can be miniaturized, the microphone assumes the same basic configuration and structure as that of the DC-biased capacitor microphone. Even in this case, any one of electrodes is connected to the ground line (the ground potential), whereupon signal charges flow into the ground line. Therefore, consideration has never been given to utilization of the signal charges in both electrodes.

From the above, the balance signal output type sensor according to the first embodiment of the present invention is characterized as being able to effectively utilize signal charges developed in both electrodes of the capacitor unit.

In the capacitor unit making up the related-art electret capacitor sensor, the first electrode 101 or the second electrode, which is one of the mutually opposed electrodes, is connected to the ground line. Therefore, a signal of only one electrode is utilized, and a signal utilization factor (efficiency) is 50%. Accordingly, adopting a configuration in which neither the first electrode nor the second electrode is connected to the ground, there is yielded an advantage of the signal utilization factor coming to 100%. It can also be said that an advantage of sensitivity being approximately doubled is yielded.

As a result of an electret film being formed at the first electrode or the second electrode, there is obviated a necessity to connect the respective electrodes to connection lines for feeding electric charges (voltages) to the respective electrodes, influence of the connection lines is eliminated. There is, therefore, yielded an advantage of signals acquired from the respective electrodes becoming more complementary signals.

Consideration is now given to voltages output from the balance signal output terminals 120 and 123 of the first and second amplifiers 201 and 202 while the MEMS microphone having the floating structure is taken as a signal source. The first and second amplifiers 201 and 202 are inverting capacitively coupled charge amplifiers.

In the first and second amplifiers 201 and 202, a virtual short-circuit occurs between the inverting input terminal 212 and the non-inverting input terminals 211 and between the inverting input terminal 221 and the non-inverting input terminal 222, as in an ordinary inverting amplifier.

Input impedance of the inverting input terminals 212 and 221 becomes infinite by the virtual short-circuit, and an electric current does not flow into the non-inverting input terminals. The second electrode terminal 112 is virtually grounded by the virtual short-circuit, so that the second amplifier 202 does not affect the first amplifier 201. Likewise, the first electrode terminal 111 is virtually grounded, so that the first amplifier 201 does not affect the second amplifier 202.

Accordingly, the electric charges existing in the first electrode 101 flow into the feedback capacitor 214 and the feedback resistor 213, and the electric charges existing in the second electrode 102 flow into the feedback capacitor 224 and the feedback resistor 223.

Capacitance values of the respective feedback capacitors 214 and 224 are taken as C_{f}, and resistance values of the feedback resistors 213 and 223 are taken as R_{f}. The balance signal outputs 120 and 123 are represented as follows by the foregoing signal charges and capacitance of the MEMS microphone.

$$[ Mathematical Expression 4 ]$$

$$Balance signal output 120 \text{:} - \frac{\{ + Δ {q}_{1} sin ( ω t ) \}}{{C}_{f}} = - \frac{{C}_{m 1}}{{C}_{f}} Δ {V}_{1} sin ( ω t )$$

$$Balance signal output 123 \text{:} - \frac{\{ - Δ {q}_{1} sin ( ω t ) \}}{{C}_{f}} = + \frac{{C}_{m 1}}{{C}_{f}} Δ {V}_{1} sin ( ω t )$$

where Δq₁=Δq₁=CₘₜΔV₁,Cₘₜ−Cₘ

Moreover, a low-pass cutoff filter that can be determined from the feedback resistors 213 and 223 and the feedback capacitors 214 and 224 is formed. Therefore, the above expression stands at a frequency range that is higher than a cutoff frequency f_{cut} which will be described below. The Lower cutoff frequency f_{cut} can be determined in consideration of an operating band of the MEMS microphone.

$$[ Mathematical Expression 5 ]$$

$$Lower cutoff frequency \text{:} {f}_{cut} = \frac{1}{2 π {C}_{f} {R}_{f}} [ Hz ]$$

As can be seen from the above expression, the two balance signal output terminals 120 and 123 can produce, by the foregoing connection configuration, complementary signals (signals that have the same magnitude and that are opposite in phase to each other) commensurate with complementary signal charges developed in the first electrode 101 and the second electrode 102 that oppose each other and that are included in the balance signal output type sensor.

If the complementary signals are subjected to balance connection processing (subtraction processing), a double-sized signal is acquired, and noises input to the MEMS microphone in phase with the complementary signals can be canceled.

As can be seen from the expression, the pieces of parasitic capacitance 109 and 110 exist but become non-sensitive to signal transmission.

Noises appearing in the balance signal output terminals 120 and 123 are now discussed.

As mentioned previously, the second amplifier 202 does not affect the first amplifier 201 by the virtual short-circuit in the first and second amplifiers 201 and 202. Likewise, the first amplifier 201 does not affect the second amplifier 202. Therefore, a noise factor appearing in the balance signal output terminal 120 of the first amplifier 201 includes capacitance Cₘ₁ of the MEMS microphone, noise of the first amplifier 201, feedback capacitance C_{f}, and feedback resistance R_{f}. A noise factor appearing in the balance signal output terminal 123 includes the capacitance Cₘ₁ of the MEMS microphone, the noise of the second amplifier 202, the feedback capacitance C_{f}, and the feedback resistance R_{f}. Since the factors are identical with each other, the noises become equal to each other in terms of a magnitude. Accordingly,

[Mathematical Expression 6]

Provided that

noises appearing in the balance signal output terminal 120: V_{N1}; and that

noises appearing in the balance signal output terminal 123: V_{N1},

a signal-to-noise ratio achieved when one electrode of the related art MEMS microphone is connected to the ground is defined as:

$${( S / N )}_{1} = \frac{\frac{{C}_{m 1}}{{C}_{f}} Δ {V}_{1}}{{V}_{N 1}}$$

A signal-to-noise ratio achieved when the signal of the present invention is subjected to balance connection processing is defined as below,

$$S / N = \frac{2 \cdot \frac{{C}_{m 1 }}{{C}_{f}} Δ {V}_{1}}{\sqrt{{V}_{N 1}^{2} + {V}_{N 1}^{2}}} = \sqrt{2} \frac{\frac{{C}_{m 1 }}{{C}_{f}} Δ {V}_{1}}{{V}_{N 1}} = \sqrt{2} \cdot {( S / N )}_{1}$$

and a signal-to-noise ratio is enhanced by a factor of √2 (3 dB).

A balance signal having higher quality can be fed.

By use of the signals that are produced from the first and second electrodes in a capacitor unit, like an MEMS microphone, and that are complementary to each other, mixed extraneous noises can be canceled by the configuration, so that a balance signal output type sensor can be provided. Reasons for the ability to cancel noises are that, since noises mixed into the first electrode and the second electrode are in phase, the noises can be canceled by subjecting the complementary signals to subtraction processing.

Moreover, by the connection configuration that makes it possible to effectively utilize the signals that are complementary to each other, a loss is reduced, and sensitivity can be enhanced.

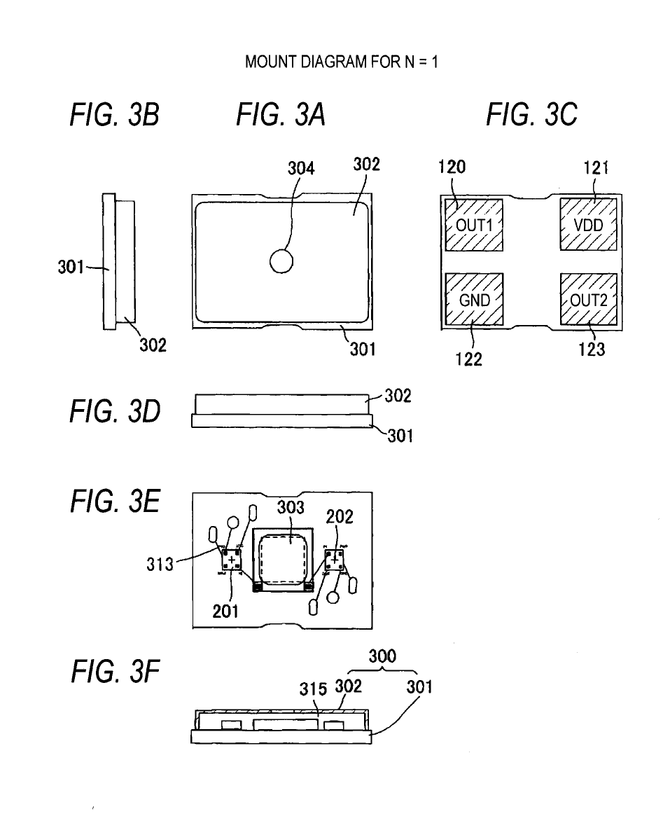

A general mount diagram of the balance signal output type sensor of the first embodiment of the present invention are now described. FIGS. 3A to 3F are general mount diagrams of the balance signal output type sensor of the first embodiment of the present invention.

FIG. 3A is a top view of the balance signal output type sensor (a module), FIG. 3B is a left side view of the same, FIG. 3C is a bottom view of the same, FIG. 3D is a front view of the same, FIG. 3E is a top view of the balance signal output type sensor (the module) from which a metal cap is removed, and FIG. 3F is a cross sectional view of a balance signal output type sensor (the module). FIGS. 3A to 3F show a mounted state of the sensor achieved when one capacitor unit exists.

As shown in FIGS. 3A to 3F, the balance signal output type sensor is configured as a result of the first amplifier 201, the second amplifier 202, and an MEMS microphone chip (the MEMS element unit) 303 are housed in the case 300 made up of a printed board 301 and a metal cap 302. The first amplifier 201 and the first electrode of the MEMS microphone chip 303 are connected together by a bonding wire 313, and the second amplifier 202 and the second electrode of the MEMS microphone chip 303 are connected together by the bonding wire 313. An inlet port 304 for introducing sound and pressure is formed in the metal cap 302. The balance signal output terminal 120 of the first amplifier, a voltage (power) feed terminal 121 for feeding a voltage to the first amplifier and the second amplifier, the ground terminal 122, and the balance signal output terminal 123 of the second amplifier are formed on a face opposite to a face of the printed board 301 on which the first amplifier, the second amplifier, and the MEMS microphone chip 303 are mounted. A face mount terminal structure is thus formed. The printed board 301 and the metal cap 302 are bonded together by solder reflow, or the like.

The inlet port 304 does not always need to be formed in the metal cap 302 but may also be formed in the printed board 301. Specifically, the inlet port 304 can be formed by subjecting the printed board 301 to boring. When the inlet port 304 is formed in the printed board 301, especially, when the inlet port 304 is arranged at a location of the printed board 301 immediately below the MEMS microphone chip 303, sound is entered into the MEMS microphone chip 303 from the location immediately below the MEMS microphone chip 303. Also, when the inlet port 304 is provided at a location on the printed board 301 where the MEMS microphone chip 303 is not mounted, the sound introduced from the inlet port 304 is diffracted or reflected by the metal cap 302 whereby the sound is entered into the MEMS microphone chip 303 from above of the MEMS microphone chip 303. Since sound directly enters the MEMS microphone chip 303, it is desirable to place the inlet port 304 at a location on the printed board 301 immediately below the MEMS microphone chip 303.

The MEMS microphone chip 303, the first amplifier 201, and the second amplifier 202 are mounted on the first face of the printed board 301 by bonding. Since each of the first and second amplifiers 201 and 202 is a CMOS high input impedance amplifier that has an input terminal, a power terminal, an output terminal, and a ground terminal. The three terminals other than the input terminal are terminals that are to exchange a signal with the outside. The three terminals are also connected to the terminals 120 to 123 formed on the second face of the printed board 301. The first amplifier 201 and the second amplifier 202 each are preferably made up of an IC. The terminals 120 to 123 act as interface terminals with respect to the outside. The ground terminal 122 is electrically connected to the metal cap 302 by way of the printed board 301. The case 300 acts as a shield case that protects an interior of the case from electromagnetic noise originating from the outside having a ground potential.

The MEMS microphone chip 303 is assumed to measure about 2 mm, and the first amplifier (IC) 201 and the second amplifier (IC) 202 is also assumed to measure about 1 mm. Further, when they are assumed to be arranged as shown in FIG. 3E, a balance signal output type sensor measuring 8 mm (W)×6 mm (D)×1.3 mm (H) can be made. Depending on a layout structure and a chip size, the numerals can be made much smaller.

The dimension of 8 mm (W) is sufficiently smaller than a wavelength λ=34 [mm] of sound waves having a frequency 10 kHz. Sound waves having a wavelength of about 10 kHz are introduced by way of the inlet port 304, whereby sound pressure achieved in a cavity 315 made up of the metal cap 302 and the printed board 301 is constant. Sound pressure applied to the vibratory membrane of the MEMS microphone chip 303 also becomes constant.

Experiment data pertaining to a signal acquired by use of the balance signal output type sensor of the first embodiment of the present invention is now described.

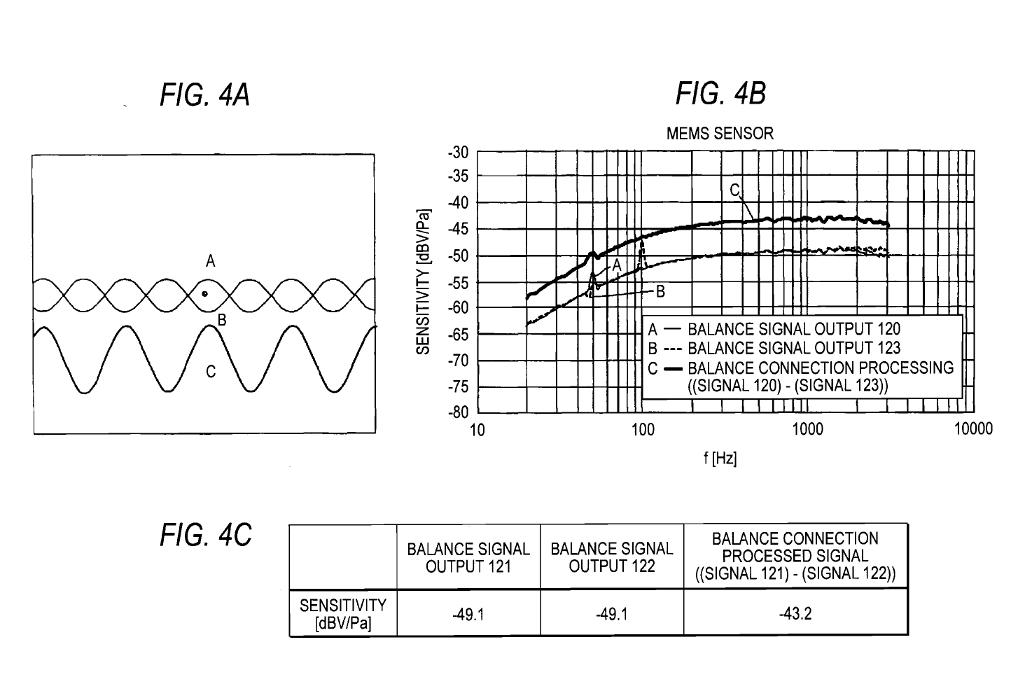

FIGS. 4A to 4C are drawings for describing an actual characteristic achieved when the number of the MEMS microphone chips in the balance signal output type sensor of the first embodiment of the present invention is one. The capacitance Cₘ of the MEMS microphone chip is 7 [pF]. The feedback capacitance C_{f} of the same is 8 [pF], and the feedback resistance R_{f} of the same is 2 [GΩ]. A general-purpose amplifier (manufactured by Texas Instruments Incorporated, TLC2201) is used for the CMOS type high input impedance amplifier.

In FIG. 4A, a horizontal axis represents a time axis. FIG. 4A shows a signal A (a balance signal output A) output from the balance signal output terminal 120, a signal B (a balance signal output B) output from the balance signal output terminal 123, and a signal C acquired after the output signal A and the output signal B have been subjected to balance connection processing. Balance connection processing refers to subtraction processing for subtracting the output signal B from the output signal A. It is seen from FIG. 4A that the output signal A and the output signal B are signals which have the same amplitude and which are opposite in phase to each other. Moreover, an amplitude of the signal C is about twice as large as an amplitude of the output signals A and B, and it is seen that the characteristic described in connection with the present invention is exhibited. Numerals given to the vertical axis are meaningless, and hence their explanations are omitted.

FIG. 4B shows a sensitivity frequency characteristic of the microphone. As can be seen From 4B, the output signal A and the output signal B are understood to exhibit substantially the same sensitivity. Sensitivity of the signal C is understood to be about twice as large as the sensitivity of the output signal A and the output signal B (by about 6 dB). The signal subjected to balance connection processing is doubled (increased by 6 dB), and a frequency characteristic of the signal yielded in a voice band also exhibits the same tendency. Therefore, the characteristic described in connection with the present invention can be understood to be yielded from the experiment.

FIG. 4C shows sensitivity of the output signal A, the output signal B, and the signal C achieved when a sound wave of about 1000 Hz has reached the balance signal output type sensor. A result of this experiment also shows that the sensitivity of the signal C is about twice as large as the sensitivity of the output signal A and the output signal B (by about 6 dB).

### Second Embodiment

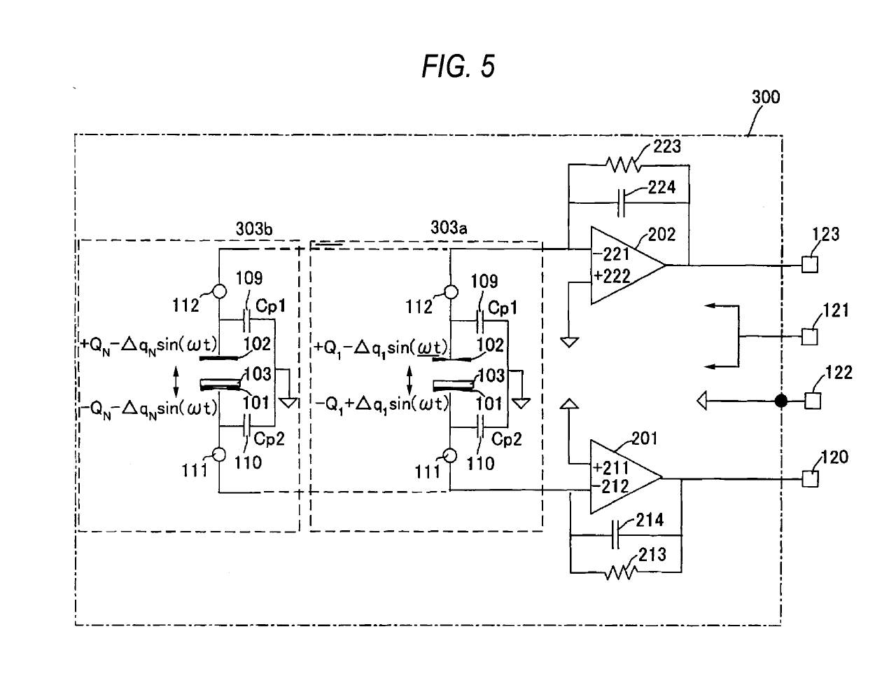

A second embodiment of the present invention is hereunder described in detail by reference to FIGS. 5 through 7. Materials and numerals used in the present invention merely illustrate a preferred embodiment, and the present invention shall not be limited to the embodiment. The present invention is susceptible to alterations, as required, without departing a scope of concept of the present invention. In addition, the present embodiment can also be combined with another embodiment. A capacitor unit of a balance signal output type sensor is an MEMS element unit. Explanations are now provided on condition that the capacitor unit is particularly an MEMS element unit having an electret. A capacitor microphone (an MEMS microphone chip) is described as an example MEMS element unit. The MEMS element unit designates a capacitor fabricated by use of a semiconductor process. The above can be said commonly to the present invention. The second embodiment of the present invention provides an explanation about a mode a case where a plurality of capacitor units are used. The embodiment provides descriptions, particularly, about a configuration including two capacitor units.

FIG. 5 is a general drawing of a circuit diagram equivalent to the balance signal output type sensor of the second embodiment of the present invention.

The first electrode 101 of the second capacitor unit is connected to the inverting input terminal 212 of the first amplifier 201 by way of the first electrode terminal 111 in much the same way as one capacitor unit descried in connection with the first embodiment. Likewise, the second electrode 102 of the second capacitor unit is connected to the inverting input terminal 221 of the second amplifier 202 by way of the second electrode terminal 112. Explanations about the second embodiment are the same as the explanations about FIG. 1 described in connection with the first embodiment, in terms of another configuration, another connection relationship, and another effect. Therefore, the explanations are hereunder omitted. Moreover, the explanations given to FIGS. 2A and 2B in the first embodiment also apply to the second embodiment, and hence the explanations are hereunder omitted. When the capacitor unit is in a number of 3 to N, first electrodes of the number 3 to N of capacitor units are connected to the inverting terminal 212 of the first amplifier 201 by way of the electrode terminals of the first electrode, as in the case of the two capacitor units. Further, the second electrodes 102 of the number 3 to N of the capacitor units are connected to the inverting input terminal 221 of the second amplifier 202 by way of respective electrode terminals of the electrode. Descriptions similar to those given to the case of two capacitor units can also be provided to the case of the number 3 to N of capacitor units by adoption of the configuration, such as that mentioned above.

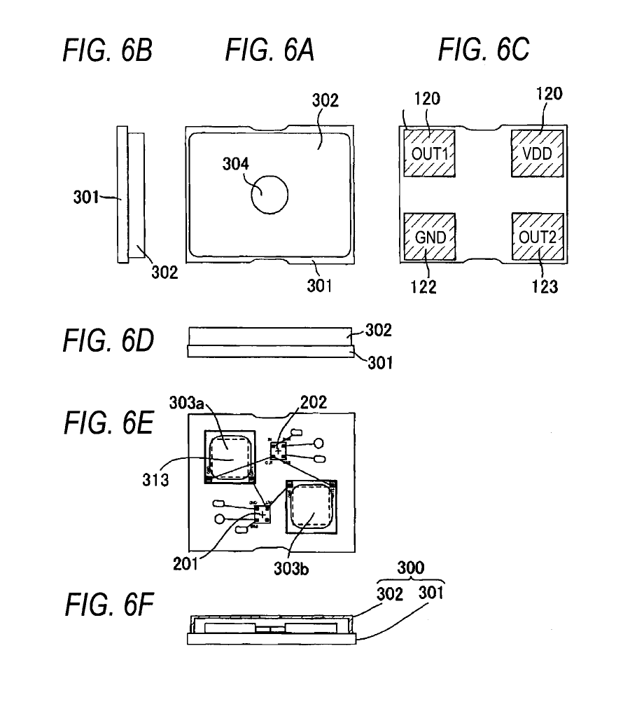

The schematic mount view of the balance signal output type sensor of the second embodiment of the present invention is now described. FIGS. 6A to 6F are schematic mount views of the balance signal output type sensor of the second embodiment of the present invention.

FIG. 6A shows a top view of the balance signal output type sensor (module), FIG. 6B shows a left side view of the same, FIG. 6C shows a bottom view of the same, FIG. 6D shows a front view of the same, FIG. 6E shows a top view of the balance signal output type sensor (module) achieved when a metal cap is removed, and FIG. 6F shows a cross sectional view of a balance signal output type sensor (module) (however, FIG. 6F provides descriptions meaning that two amplifiers are projected). FIGS. 6A to 6F show a mounted state of a sensor including two capacitor units.

The balance signal output type sensor is configured as a result of the first amplifier 201, the second amplifier 202, and two MEMS microphone chips 303a and 303b being accommodated in the case, in much the same way as one capacitor unit descried in connection with the first embodiment. The first amplifier and first electrodes of the two MEMS microphone chips 303a and 303b are connected by the bonding wire 313, and the second amplifier and the second electrodes of the two MEMS microphone chips 303a and 303b are connected by the bonding wire 313. The first electrodes of the two MEMS microphone chips 303a and 303b are connected to the single first amplifier, and the second electrodes of the two MEMS microphone chips 303a and 303b are connected to the single second amplifier. The reason for this is that the connections are preferable in view of miniaturization.

Each of the first and second amplifiers 201 and 202 has one output terminal. There is adopted a configuration in which an output from the output terminal of the first amplifier 201 is delivered to the balance signal output terminal 120 of the first amplifier 201 on a back mount face of the printed board 301. An output from an output terminal of the second amplifier 202 is delivered to the balance signal output terminal 123 of the second amplifier 202 on the back mount face of the printed board 301. The reason for this is that the configuration is preferable in terms of a connection loss.

Explanations about the second embodiment are the same as the explanations about FIG. 3 described in connection with the first embodiment, in terms of another configuration, another connection relationship, and another effect, hence, their explanations are omitted. Descriptions similar to those given to the case of two capacitor units can also be provided to the case of the number 3 to N of MEMS microphones (capacitor units) by adoption of the configuration, such as that mentioned above.

In the balance signal output type sensor of the second embodiment of the present invention, the MEMS microphones each of which has the floating structure are taken as signal sources, and consideration is now given to voltages output from the balance signal output terminals 120 and 123 of the first and second amplifiers 201 and 202. Ideas are further developed from the case where two MEMS microphones are provided. To this end, consideration is now given to a case where a plurality of (a number N of) MEMS microphones are connected in parallel.

When a plurality of (a number N of) MEMS microphones are connected in parallel, the same discussion as that provided in connection with the first embodiment (N=1) comes into effect, and hence a balance signal output is represented as follows:

$$[ Mathematical Expression 7 ]$$

$$The balance signal output terminal 120 produces a balance signal output \text{:} {\sum }_{i = 1}^{N} - \frac{\{ + Δ {q}_{1} sin ( ω t ) \}}{{C}_{f}} = - {\sum }_{i = 1}^{N} \frac{{C}_{m 1}}{{C}_{f}} Δ {V}_{1} sin ( ω t )$$

$$The balance signal output terminal 123 produces a balance signal output \text{:} {\sum }_{i = 1}^{N} - \frac{\{ - Δ {q}_{1} sin ( ω t ) \}}{{C}_{f}} = + {\sum }_{i = 1}^{N} \frac{{C}_{m 1}}{{C}_{f}} Δ {V}_{1} sin ( ω t )$$

Further, because of evenness of manufacture of the MEMS microphone chips, the following relationships are derived.

Δq₁=Δq₂= . . . =Δ_{N}

Cₘ₁=Cₘ₂= . . . C_{mN}=Cₘ

ΔV₁=ΔV₂= . . . =ΔV_{N}

Therefore, the following equations are derived:

Balance signal output terminal 120:

$$- N \cdot \frac{\{ + Δ {q}_{1} sin ( ω t ) \}}{{C}_{f}} = - N \cdot \frac{{C}_{m 1}}{{C}_{f}} Δ {V}_{1} sin ( ω t )$$

Balance signal output terminal 123:

$$+ N \cdot \frac{\{ + Δ {q}_{1} sin ( ω t ) \}}{{C}_{f}} = + N \cdot \frac{{C}_{m 1}}{{C}_{f}} Δ {V}_{1} sin ( ω t )$$

A superior signal that is enhanced by 2·N times can be obtained as a signal subjected to balance connection processing.

As in the case of N=1, signal-to-noise ratios of the respective balance signal outputs are enhanced as follows.

$$[ Mathematical Expression 8 ]$$

$$Noise appearing in the balance signal output terminal 120 is defined a s \text{:} \sqrt{{\sum }_{i = 1}^{N} {V}_{Ni}^{2}}$$

$$Noise appearing in the balance signal output terminal 123 is defined a s \text{:} \sqrt{{\sum }_{i = 1}^{N} {V}_{Ni}^{2}}$$

Like a signal output, the following relationship stands:

V_{N1}=V_{N2}= . . . =V_{NN}

Therefore, we have

noise appearing in the balance signal output terminal 120:

$$\sqrt{{\sum }_{i = 1}^{N} {V}_{N 1}^{2}} = \sqrt{N} {V}_{N 1}$$

noise appearing in the balance signal output terminal 123:

$$\sqrt{{\sum }_{i = 1}^{N} {V}_{N 1}^{2}} = \sqrt{N} {V}_{N 1}$$

In contrast with the signal-to-noise ratio achieved when one of the electrodes of the related art microphone chip is grounded: namely,

$${( S / N )}_{1} = \frac{\frac{{C}_{m 1}}{{C}_{f}} Δ {V}_{1}}{{V}_{N 1}} ,$$

we have a signal-to-noise ratio for a case where the signal of the present invention is subjected to balance connection processing:

$$\begin{matrix}S / N = \frac{2 \cdot N \cdot \frac{{C}_{m 1}}{{C}_{f}} Δ {V}_{1}}{\sqrt{{( \sqrt{N} {V}_{N 1} )}^{2} + {( \sqrt{N} {V}_{N 1} )}^{2}}} \\ = \sqrt{2 \cdot N} \frac{\frac{{C}_{m 1 }}{{C}_{f}} Δ {V}_{1}}{{V}_{N 1}} \\ = \sqrt{2 \cdot N} \cdot {( S / N )}_{1} .\end{matrix}$$

When a number N of MEMS microphone chips are connected and subjected to balance connection processing, the signal-to-noise ratio is also enhanced by \sqrt{2·N}.

Thus, a balance signal having superior quality can be fed.

Even when a plurality of microphone chips are connected, noise input in phase to the balance signal output type sensor chip (a capacitor unit) can be canceled as in the case of N=1.

Experiment data pertaining to the signals acquired by use of the balance signal output type sensor according to the second embodiment of the present invention are now described.

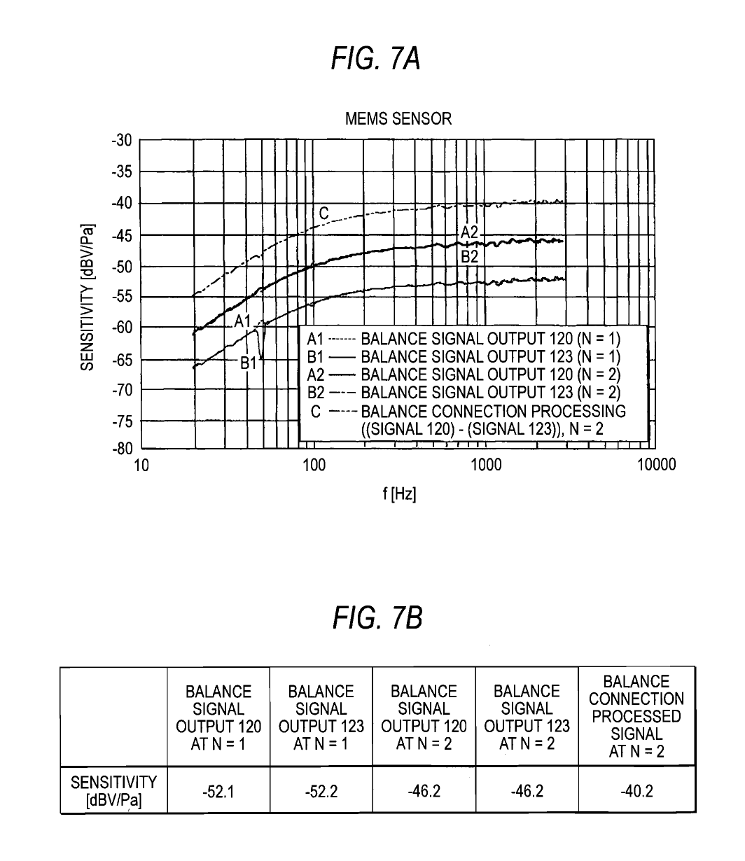

FIGS. 7A and 7B are views for describing actual characteristics achieved when one MEMS microphone chip is provided and when two MEMS microphone chips are provided, in connection with the balance signal output type sensor of the second embodiment of the present invention. The MEMS microphone chip herein has capacitance Cₘ of 5 [pF], feedback capacitance C_{f} of 8 [pF], and feedback resistance R_{f} of 2 [GΩ]. A general-purpose amplifier (manufactured by Texas Instruments Incorporated, TLC2201) is used for the CMOS type high input impedance amplifier.

FIG. 7A shows a sensitivity frequency characteristic of the microphone. In FIG. 7A, an output signal A1 represents a signal output from the balance signal output terminal 120 when the MEMS microphone chip is in the number of one. An output signal B1 represents a signal output from the balance signal output terminal 123 when the MEMS microphone chip is in the number of one. An output signal A2 represents a signal output from the balance signal output terminal 120 when the MEMS microphone chip is in the number of two. An output signal B2 represents a signal output from the balance signal output terminal 123 when the MEMS microphone chip is in the number of two. Further, reference symbol C represents an output signal C obtained after the output signal A2 and the output signal B2 have been subjected to balance connection processing. Balance connection processing herein refers to subtraction processing for subjecting the output signal A2 and the output signal B2 to subtraction.

As is obvious from FIG. 7A, the output signal A1 and the output signal B1 are substantially identical with each other in terms of sensitivity. Likewise, the output signal A2 and the output signal B2 are understood to be substantially identical with each other in terms of sensitivity. Sensitivity of the output signals A2 and B2 is understood to become substantially double (become greater by about 6 dB than) the sensitivity of the output signal A1 and the sensitivity of the output signal B1 (by 6 dB). Moreover, the sensitivity of the signal C is understood to become substantially double (become greater by about 6 dB than) the sensitivity of the output signal A2 and the sensitivity of the output signal B2.

FIG. 7B represents sensitivity of the output signal A1, the output signal B1, that of the output signal A2, that of the output signal B2, and that of the output signal C achieved when a sound wave of about 1000 Hz has reached the balance signal output type sensor. Results show that teaching represented by FIG. 7A is understood to apply to this case, either.

Since the two MEMS microphone chips are stored in the case, there is used an MEMS microphone chip that is smaller than that used when one MEMS microphone chip is stored. For this reason, the capacitance Cₘ of the MEMS microphone (the capacitor unit) also becomes smaller. In the meantime, since the two MEMS microphone chips are fabricated on a single wafer, characteristics of the chips have a difference of sensitivity of 0.3 dB or less.

When the MEMS microphone chip is one, the balance output signal A1 is −52.1 [dBV/Pa], and the balance output signal B1 is −52.2 [dBV/Pa]. When the MEMS microphone chip is in the number of two, the balance output signal A2 is −46.2 [dBV/Pa], and the balance output signal B2 is −46.2 [dBV/Pa]. Therefore, when the MEMS microphone chips are in the number of two, the sensitivity of the chips is understood to be set so as to fall within the difference of 0.3 dB. Experimental results show that the signals subjected to balance connection processing when the MEMS microphone chip is in the number of two (N=2) exhibit a characteristic enhanced by 2·N times (12 dB).

Since a plurality of microphone chips are simultaneously incorporated into the MEMS microphone chip by utilization of processes of manufacturing a CMOS. Therefore, a uniform characteristic and even sensitivity and capacitance are yielded. Therefore, displacements of the respective vibratory membranes are substantially of the same magnitude. When a plurality of microphone chips are used in the form of a multiple connection, noise can be canceled with superior efficiency, so that outputs having uniform characteristics can be obtained. When a plurality of MEMS microphones are connected to a single board, interconnection of the microphones becomes unnecessary, and a superior balance signal output type sensor not including a connection loss can be provided. The first and second amplifiers as well as the plurality of MEMS microphones are integrated on a single substrate, whereby a superior balance signal output type sensor that is extremely fine and that is free of connection loss can be provided. From the above, as described in connection with the second embodiment of the present invention, the plurality of capacitor units (the MEMS element units) are mounted, there is yielded an advantage of the ability to provide a balance signal output type sensor exhibiting the advantage such as that mentioned above. The present invention is not required to yield all of the advantages mentioned above. So long as any one of the advantages is yielded, the present invention is sufficiently useful.

The functions of the first and second amplifiers 201 and 202 described in connection with the first embodiment and the second embodiment can be implemented in the form of one IC, and the IC can also be additionally imparted with a subtraction processing function.

### First Modification

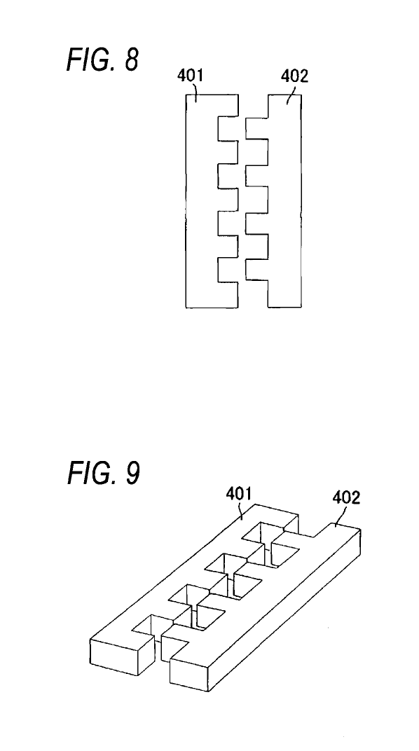

A first modification of the present invention is hereunder described by reference to FIGS. 8 and 9.

Although the electrodes having smooth mutually opposed faces are used in the first and second embodiments, electrodes whose mutually opposed faces have a combtooth structure can also be used. Specifically, it is also possible to use, as a capacitor unit, a pair of capacitor structures including a combtooth movable electrode and a combtooth stationary electrode, which face opposite each other. FIG. 8 shows a cross sectional view of a pair of electrodes whose mutually opposed faces have a combtooth structure. FIG. 9 shows an oblique perspective view of the pair of electrodes whose mutually opposed faces have a combtooth structure.

In the first modification of the present invention, first and second electrodes 401 and 402 produce outputs while connected to the first and second amplifiers 201 and 202 in much the same way as the first and second embodiments of the present invention, and none of them are connected to the ground. The first modification differs from the first and second embodiments only in that the first electrode 401 that is a movable electrode and the second electrode 402 that is a stationary electrode assume a shape of a combtooth.

When compared with a case where the combtooth structure is not provided, the above configuration yields an advantage of the ability to increase an area where capacitance develops.

### Second Modification

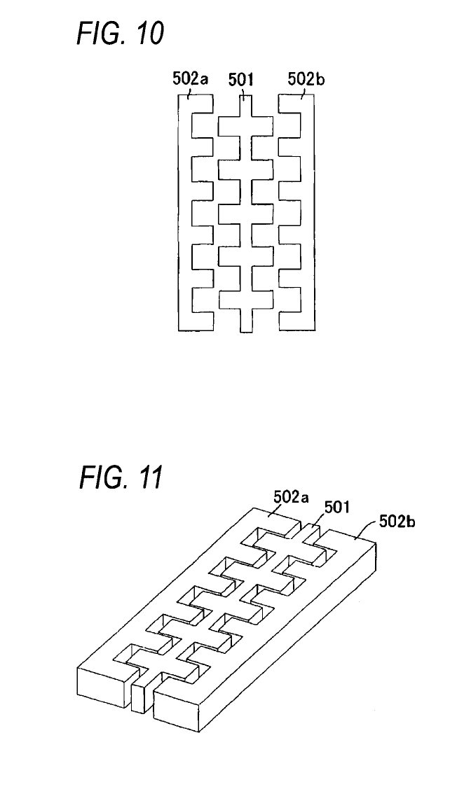

A second modification of the present invention is hereunder described by reference to FIGS. 10 and 11.

The first modification employs, as a capacitor unit, the pair of capacitor structures including the combtooth movable electrode 401 and the combtooth stationary electrode 402, which oppose each other. As illustrated in a cross sectional view of FIG. 10 and an oblique perspective view of FIG. 11, in the second modification, second electrodes 502a and 502b that are to serve as combtooth stationary electrodes are placed opposite each other on both faces of a first electrode 501 that is to serve as a movable electrode whose both faces assume a shape of a combtooth.

In the second modification of the present invention, the first and second electrodes 501, 502a, and 502b produce outputs while connected to the first and second amplifiers 201 and 202 in the same way as the first and second embodiments of the present invention, and none of them are connected to the ground. The second modification differs from the first and second embodiments only in that the second electrodes 502a and 502b which are combtooth stationary electrodes are disposed opposite each other on both faces of the first electrode 501 which is to serve as a movable electrode whose both faces assume a shape of a combtooth.

By the configuration, there is yielded an advantage of the ability to produce a change in capacitance that is twice as large as that produced in the first modification, so long as the combtooth electrode is provided in two pairs.

### Third Modification

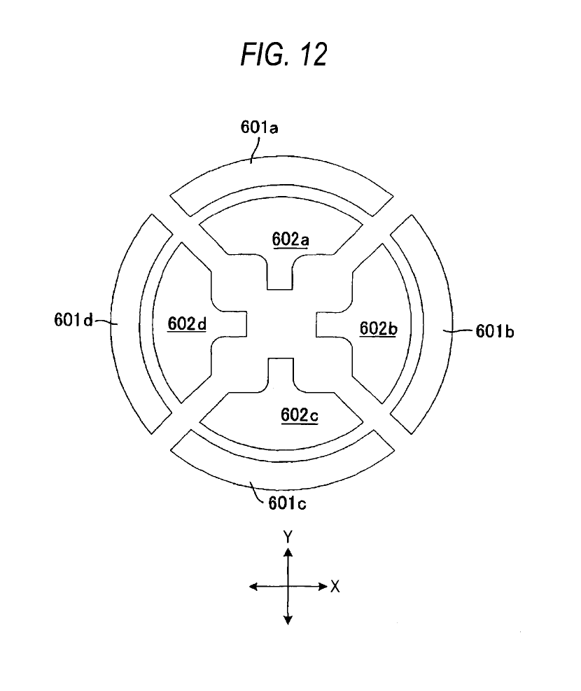

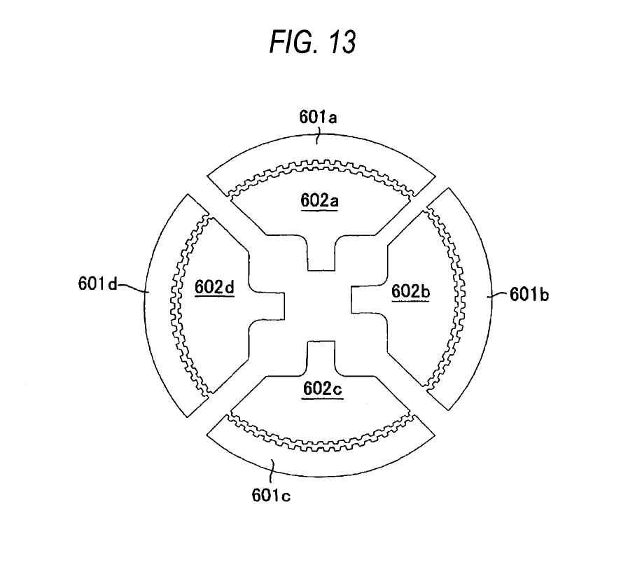

A third modification of the present invention is hereunder described by reference to FIGS. 12 and 13.

In the third modification, four pairs of capacitor units are made, and two pairs of them detect acceleration developed in a direction X, and the other two detect acceleration developed in a direction Y. As represented by a cross sectional view of FIG. 12, first electrodes 601a to 601d, which are movable electrodes, are formed so as to become split in four along a circumference. Second electrodes 602a through 602d are disposed opposite respective interior sides of the first electrodes 601a to 601d. Alternatively, it is also possible to adopt a configuration in which the first electrodes 601a to 601d that are to serve as movable electrodes are located inside of the second electrodes 602a to 602d.

In the third modification of the present invention, the first electrodes 601a to 601d and the second electrodes 602a to 602d produce outputs while connected to the first and second amplifiers 201 and 202, in much the same way as the first and second embodiments of the present invention, and none of them are connected to the ground. The third modification differs from the first and second embodiments only in that the four pairs of capacitor units are made and arranged in such a way that the two pairs of capacitor units can detect acceleration developed in the direction X and that the other two pairs can detect acceleration developed in the direction Y. In the third modification of the present invention, the first electrodes 601a to 601d that are movable electrodes even in the present modification and the second electrodes 602a to 602d that are stationary electrodes even in the present modification each may also assume a shape of a comb and may also be disposed opposite each other, as shown in FIG. 13. Even in connection with a configuration, such as that shown in FIG. 13, there may also be adopted a configuration in which the first electrodes 601a to 601d that are to serve as movable electrodes are disposed inside of the second electrodes 602a to 602d.

By the configuration, it is possible to configure an acceleration sensor for detecting amounts of changes developed in both the directions X and Y.

Even in the first through third modifications, it is desirable to provide the first or second electrode with an electret film or a dielectric film. The word “balance signal output type sensor” used herein designates a sensor that uses a pair of signal lines and that outputs so-called balance signals which are of the same magnitude and opposite in phase to each other.

### Third Embodiment

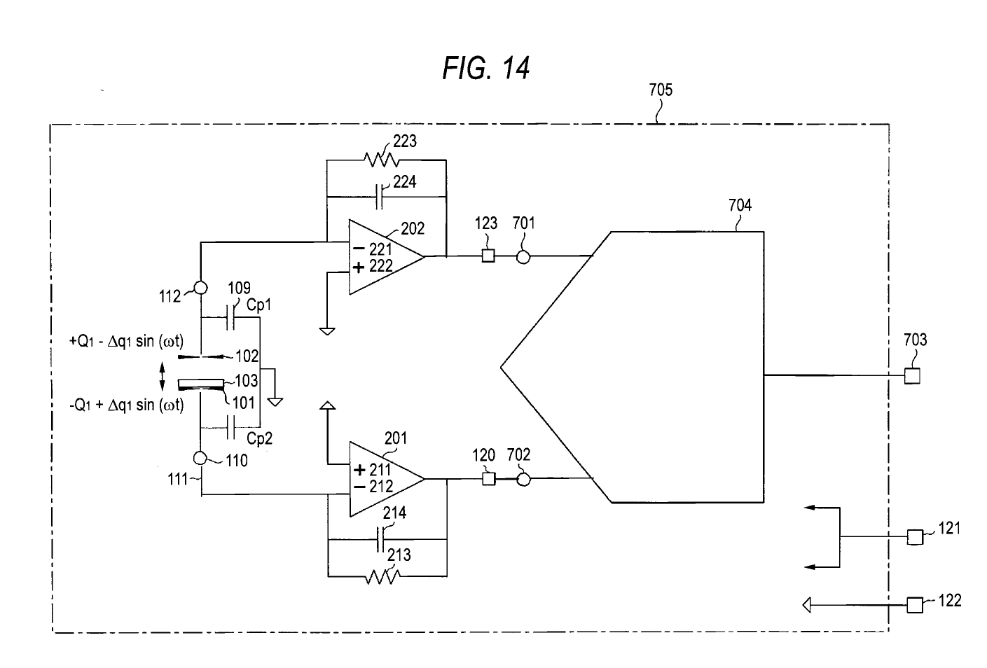

A third embodiment of the present invention is now described. FIG. 14 is a general drawing showing a connection configuration of a digital signal output sensor in the embodiment of the present invention.

The digital signal output sensor is made up of a case constituent element 705. The balance signal output terminal 120 of the first amplifier 201 of the balance signal output type sensor described in connection with the first embodiment is connected to an input terminal 702 of an analogue-to-digital converter 704, and the balance signal output terminal 123 of the second amplifier 202 is connected to an input terminal 701 of the same. An output from the analogue-to-digital converter is delivered to an output terminal 703.

The analogue-to-digital converter 704 and the first and second amplifiers 201 and 202 are configured on a single chip by utilization of the manufacturing process technique, whereby the power feed terminals 121 and the ground terminal 122 can be made commonly useful.

Further, the analogue-to-digital converter 704 and the first and second amplifiers 201 and 202 are configured on a single chip, whereby the analogue-to-digital converter 704 and the first and second amplifiers 201 and 202 are implemented in the form of one common circuit, for instance, one low-voltage generation circuit. It thereby becomes possible to lower power consumption and reduce a chip size, so that a cheaper digital output sensor can be provided.

The analogue-to-digital converter 704 of the digital signal output sensor made by use of an electret MEMS microphone is desirably a A sigma modulator characterized in high resolving power.

In particular, a high signal-to-noise ratio can be implemented at low power consumption by use of a fourth-order Δ sigma modulator having a clock frequency of 1 M to 4 MHz and a 50× to 64× oversampling rate.

The output terminal 703 of the digital signal output sensor produces an output in the form of PDM (Pulse Density Modulation) that represents a waveform rather than by density of a pulse having a given width. The output is converted into an audio interface format, for instance, an SPDIF format, by an external DSP (Digital Signal Processor). The DSP is incorporated into the case constituent element 705, whereby the output terminal 703 of the digital signal output sensor can also produce an output in the form of an audio interface format, for instance, an SPDIF format.

In order to enhance a signal-to-noise ratio f the balance signal output terminals 120 and 123 as mentioned in connection with the first embodiment, the balance signal output terminals 120 and 123 are connected to the input terminals 702 and 701 of the analogue-to-digital converter 704. The signal-to-noise ratio of the digital signal output sensor is thereby enhanced, so that a digital output signal having superior quality can be fed.

Even when the plurality of electret MEMS microphones are connected as described in connection with the second and third embodiments, the signal-to-noise ratio is enhanced further, hence, a digital output signal having superior quality can be fed.

### Fourth Embodiment

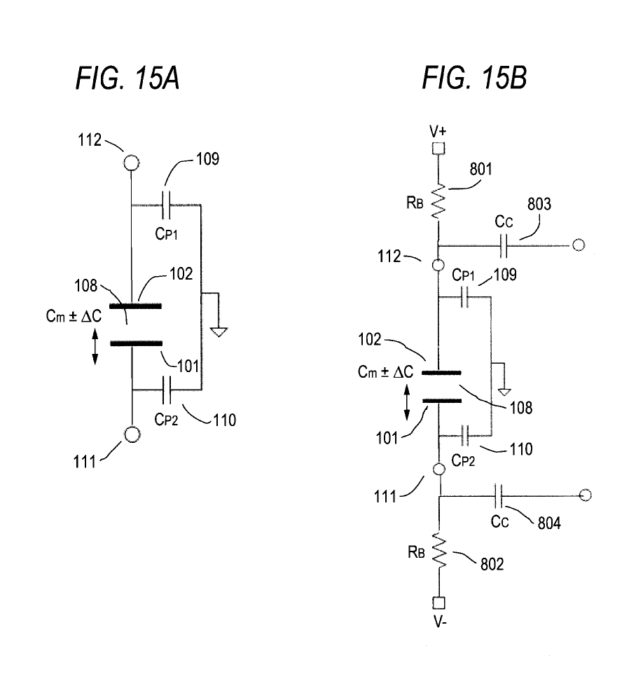

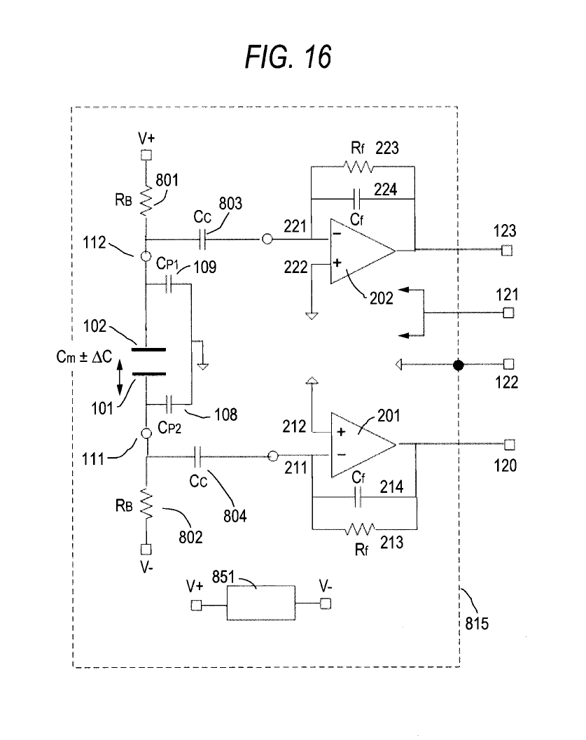

A fourth embodiment is hereunder described in detail by reference to FIGS. 15 and 16. Materials and numerals used in the present embodiment are mere preferred illustrations. The present invention is not limited to the embodiment. The present invention is susceptible to alterations, as required, without departing the scope of concept of the present invention. In addition, the present embodiment can also be combined with other embodiments. Although explanations are provided by taking a capacitor microphone as an example sensor, the following structure can also be used for another sensor, like a pressure sensor and an acceleration sensor. A capacitor unit of the capacitor microphone is an MEMS element unit. In particular, explanations are provided by taking an MEMS element unit not having an electret film as a example.

The MEMS capacitor element unit not having an electret film assumes a structure embodied by removing the electret film 103 from the structure shown in FIG. 2A. Specifically, the capacitance element unit is illustrated in a circuit diagram shown in FIG. 15A.

In order to supply a DC bias voltage to the MEMS element unit and to thus extract a signal therefrom, a positive DC bias voltage V+ is applied to the electrode terminal 112 shown in FIG. 15A through a resistor 801, as shown in FIG. 15B, and a coupling capacitor 803 is additionally connected to the electrode terminal 112.

A negative DC bias voltage V− is likewise applied to the other electrode terminal 111 through a resistor 802, and a coupling capacitor 804 is additionally connected to the electrode terminal 111.

If VB/2=|V+|=|V=| is derived, a voltage VB corresponding to the electret voltage is applied to the MEMS element unit by a connection, such as that mentioned above. Here, the voltage VB is a DC bias voltage applied to the MEMS element unit.

The first electrode 101 acting as a movable electrode is vibrated by sound waves, which in turn causes minute changes in capacitance. By the foregoing bias voltage ΔB, ±Δq₁ develops in the first and second electrodes as a minute charge variation.

The coupling capacitors 803 and 804 are used for cutting a DC bias voltage, to thus read the minute charge variation ±Δqₗ. As a result of the MEMS capacitance element unit not having an electret film being provided with such a connection configuration, the MEMS capacitance element unit can be provided with a function substantially equivalent to that of the MEMS capacitance element unit that has an electret film and that has been described in the first embodiment.

FIG. 16 is a general drawing of a circuit equivalent to the balance signal output microphone of the present embodiment. The first amplifier 201, the first feedback capacitor 214, the first feedback resistor 213, the second amplifier 202, the second feedback capacitor 224, the second feedback resistor 223, and the terminals 123, 121, 122, and 120 exhibit the same functions as those exhibited by their counterparts described in connection with the first embodiment.

In relation to a connection configuration, the MEMS element unit having the connection configuration shown in FIG. 15B is connected to the input terminal of the first amplifier 201 and the input terminal of the second amplifier 202.

Specifically, the coupling capacitor 804 of the MEMS element unit shown in FIG. 15B is connected to the inverting input terminal 212 of the first amplifier 201, and the coupling capacitor 803 is connected to the inverting input terminal 221 of the second amplifier 202.

A voltage generation section 851 generates the bias voltages V+ and V− and is connected to the resistors 801 and 802.

When capacitance of the coupling capacitors 803 and 804 is made sufficiently greater than the capacitance Cₘ of the MEMS element unit, for instance, set to a value that is about 30 times as large as the capacitance Cₘ, impedance of the coupling capacitors can be deemed to be equivalent to an electrically short-circuited state when viewed from the MEMS element unit.

The resistance of the resistors 801 and 802 is made sufficiently large. For instance, a low roll-off frequency fL determined by the capacitance Cₘ of the MEMS element unit and the resistance of the resistor is set to, e.g., 2 Hz or thereabouts. Thereby, when viewed from the MEMS element unit, the resistors can be deemed to be an electrically open state at a band of 20 Hz or more.

The low roll-off frequency fL is represented by fL=1/(2πCmRB).

Here, reference symbol RB designates resistance values of the respective resistors 801 and 802. The expression of fL exists between the resistor 801 and the capacitance 109 (Cₘ) of the element capacitor unit, and the expression of fL also exists between the resistor 802 and the capacitance 108 (Cₘ) of the element capacitor unit.

Electric charges +Δq₁ of the first electrode 101 do not flow into the resistor 802 because of the above connection but flow into the feedback capacitor 214 by way of the coupling capacitor 804.

Likewise, electric charges −Δq₁ of the second electrode 102 do not flow into the resistor 801 but flow into the feedback capacitor 214 by way of the coupling capacitor 803.

Accordingly, by the sound pressure applied to the capacitor unit of the MEMS element, a minute voltage change having an opposite polarity appears on the output terminals 123 and 120 without involvement of any substantial loss as in the case of the first embodiment.

A voltage of the output terminal 120: −Cₘ/CfΔV₁ sin(ωt)

A voltage of the output terminal 123: +Cₘ/CfΔV₁ sin(ωt)

where Δq₁=CₘΔVₗ.

Specifically, even in the case of the DC bias capacitor microphone, a balance signal output microphone can be formed at a band ranging from 300 Hz to 4000 Hz that is a voice band, so long as the foregoing configuration is adopted.

Further, when the resistors 801 and 802, the coupling capacitors 803 and 804, and the amplifiers 201 and 202 are packaged into an IC, these elements can be accommodated into the IC.

The voltage generation section 851 can also be incorporated as a voltage pump system into the IC.

Therefore, a module similar to that shown in FIG. 3 in connection with the first embodiment can be formed. Moreover, the present invention can also apply to the connection configurations shown in FIG. 5, FIG. 6, and FIG. 14.

The disclosure of Japanese Patent Application No. 2008-328492 filed on Dec. 24, 2008 including specification, drawings and claims is incorporated herein by reference in its entirety.

The present invention relates to a balance signal output type sensor that effectively uses signal charges of both polarities on mutually-opposed electrodes of the balance signal output type sensor, to thus be able to cancel mixed external noise, and is useful because it can provide a sensor capable of enhancing sensitivity and a signal-to-noise ratio.

### REFERENCE SIGNS LIST

101 FIRST ELECTRODE
102 SECOND ELECTRODE
103 ELECTRET FILM
111 FIRST ELECTRODE TERMINAL
112 SECOND ELECTRODE TERMINAL
120, 123 BALANCE SIGNAL OUTPUT TERMINAL
201 FIRST AMPLIFIER
202 SECOND AMPLIFIER
211, 222 NON-INVERTING INPUT TERMINAL
212, 221 INVERTING INPUT TERMINAL
213, 223 FEEDBACK RESISTOR
214, 224 FEEDBACK CAPACITOR
701, 702 INPUT TERMINAL
703 OUTPUT TERMINAL
704 ANALOGUE-TO-DIGITAL CONVERTER
705 CASE CONSTITUENT ELEMENT
801, 802 BIAS RESISTOR
803, 804 COUPLING CAPACITOR
851 VOLTAGE GENERATION SECTION

What is claimed is:

1. A balance signal output type sensor, comprising:
a capacitor unit configured to have a first electrode serving as a movable electrode and a second electrode arranged opposing the first electrode;
a first amplifier connected to the first electrode and amplifies an output signal from the first electrode; and
a second amplifier connected to the second electrode and amplifies an output signal from the second electrode.

2. The balance signal output type sensor according to claim 1, further comprising:
a case,
wherein the case contains the capacitor unit, the first amplifier, and the second amplifier.

3. The balance signal output type sensor according to claim 2, wherein the case is configured by a board and a cover member which covers the board on which the capacitor unit is mounted; and
wherein either one of the board and the cover member has an inlet port for transmitting pressure to the capacitor unit.

4. The balance signal output type sensor according to claim 3, wherein the board has a first face and a second face which is opposed to the first face;
wherein the capacitor unit, the first amplifier, and the second amplifier are provided on the first face of the board; and
wherein an output terminal of the first amplifier, an output terminal of the second amplifier, a power supply terminal, and a ground terminal are provided on the second face of the board.

5. The balance signal output type sensor according to claim 4, wherein the cover member is made of metal; and
wherein the ground terminal is electrically connected to the cover member through the board.

6. The balance signal output type sensor according to claim 1, further comprising:
an another capacitor unit configured to have a same configuration of the capacitor unit.

7. The balance signal output type sensor according to claim 6, wherein the first electrode of the capacitor unit and a first electrode of the another capacitor unit are respectively connected to an input terminal of the first amplifier; and
wherein the second electrode of the capacitor unit and a second electrode of the another capacitor unit are respectively connected to an input terminal of the second amplifier.

8. The balance signal output type sensor according to claim 1, wherein a dielectric film is formed on a face of the first electrode which faces to the second electrode or a face of the second electrode which faces to the first electrode.

9. The balance signal output type sensor according to claim 8, wherein the dielectric film is an electret film.

10. The balance signal output type sensor according to claim 1, wherein the first amplifier and the second amplifier configure a capacitively coupled charge amplifier.

11. The balance signal output type sensor according to claim 1, wherein the first amplifier and the second amplifier are formed in an Integrated circuit.

12. The balance signal output type sensor according to claim 1, wherein the output signal from the first amplifier is substantially opposite in phase to the output signal from the second amplifier.

13. The balance signal output type sensor according to claim 1, wherein the first electrode is not connected to a ground.

14. The balance signal output type sensor according to claim 1, wherein the second electrode is not connected to a ground.

15. The balance signal output type sensor according to claim 1, wherein the capacitor unit is a MEMS element unit.

16. A digital signal output type sensor comprising:
the balance signal output type sensor according to claim 1; and
an analog-digital converter that converts an analog signal to a digital signal,
wherein the analog-digital converter converts the output signal from the first amplifier and the output signal from the second amplifier and outputs a digital output signal.

17. The digital signal output type sensor according to claim 16, wherein the first amplifier, the second amplifier, and the analog-digital converter are provided on a single board.

18. The digital signal output type sensor according to claim 16, wherein the analog-digital converter is a delta-sigma converter.

19. The digital signal output type sensor according to claim 16, wherein the analog-digital converter outputs as the digital output signal a pulse density modulated with pulse density modulation process.

20. The digital signal output type sensor according to claim 19, further comprising:
a digital signal processor that converts the pulse density to an output signal in audio interface format.
